(19) United States
(12) Patent Application Publication
(10) Pub. No.: US 2026/0003003 A1
(43) Pub. Date: Jan. 1, 2026

(54) METHOD AND SYSTEM FOR ESTIMATING STATE OF CHARGE IN BATTERY CLUSTERS, ELECTRONIC DEVICE, AND STORAGE MEDIA

(71) Applicant: Shanghai Makesens Energy Storage Technology Co., Ltd., Shanghai (CN)

(72) Inventors: Peng DING, Shanghai (CN); Qiong WEI, Shanghai (CN); Enhai ZHAO, Shanghai (CN); Danfei GU, Shanghai (CN); Pingchao HAO, Shanghai (CN); Pei SONG, Shanghai (CN); Xiao YAN, Shanghai (CN); Jie ZHANG, Shanghai (CN)

(73) Assignee: Shanghai Makesens Energy Storage Technology Co., Ltd., Shanghai (CN)

(21) Appl. No.: 18/851,082

(22) PCT Filed: Aug. 16, 2022
(86) PCT No.: PCT/CN2022/112838

§ 371 Date: Apr. 21, 2025

(30) Foreign Application Priority Data
Mar. 31, 2022 (CN) 202210343744.8

(51) Int. Cl. G01R 31/388; G01R 31/367

(52) U.S. Cl. CPC G01R 31/388; G01R 31/367

(57) ABSTRACT

A method and a system for estimating a state of charge of a battery cluster, an electronic device, and a storage media are provided. The method comprises acquiring target data related to the state of charge; estimating, by an ampere-hour integration method, the state of charge based on the target data, to obtain a first estimated value; inputting the target data into a state-of-charge prediction model to estimate the state of charge and obtain a second estimated value, wherein the prediction model is obtained by training based on sample data; and determining a final estimated value of the state of charge based on the first estimated value, the second estimated value, and a first distance between the target data and the sample data. The method combines the ampere-hour integration method and the prediction model to estimate the state of charge, effectively improving the accuracy of the state of charge estimation.

### FIELD OF THE INVENTION

The present disclosure relates to the technical field of batteries, and in particular, to a method and a system for estimating a state of charge of a battery cluster, an electronic device, and a storage media.

### BACKGROUND OF THE INVENTION

State of Charge (SOC) is the charge status of a battery. In a battery management system for energy storage, SOC is critical as it not only affects the battery's State of Health (SOH), State of Energy (SOE), and State of Power (SOP), but also impacts battery safety. However, accurately estimating SOC is challenging due to the battery's nonlinear characteristics, which are influenced by factors such as temperature, usage time, and discharge rate. The national standard requires an estimation accuracy of 5% for SOC.

Currently, research on SOC primarily involves measuring related characteristic parameters of the battery, such as current, voltage, and internal resistance, and establishing corresponding functional relationships between these parameters and SOC. These functional relationships are used to correct SOC, making the accuracy of the battery's characteristic parameters crucial. The main methods for estimating SOC include the discharge experiment method, ampere-hour (Ah) integration method, open-circuit voltage (OCV) method, Kalman filter method, and combined voltage correction method.

Discharge Experiment Method: This method is relatively accurate and involves continuous discharging at a constant current to obtain the discharge capacity. This method is often used to calibrate battery capacity and is applicable to all batteries. However, it has significant drawbacks: it requires a lot of time, and it cannot be used on batteries in operation.

Ampere-hour (Ah) Integration Method: This method is the most commonly used SOC estimation method. The principle is to calculate the charge and discharge amount of the battery from the initial state to the current moment by real-time integration of the current during the battery's charge and discharge process, and then estimate the SOC of the battery. The accuracy of this method is affected by the current sensor's accuracy, and there are cumulative errors.

OCV Method: This method estimates SOC by measuring the battery's open-circuit voltage and utilizing the corresponding relationship between OCV and SOC. It is a direct method to obtain SOC. However, since the fundamental principle is to let the battery stand still until its terminal voltage recovers to the open-circuit voltage (thus eliminating polarization voltage), it requires a standing time of more than two hours, making it unsuitable for real-time online monitoring. Additionally, OCV measurement is complex, and slight changes in OCV due to battery aging can cause SOC estimation errors.

Kalman Filter Method: Based on the Ah integration method, this method optimally estimates the power system's state in terms of minimum variance. Its core concept includes recursive equations for SOC estimation and covariance matrices reflecting estimation errors. The covariance matrix provides the estimation error range. In practical applications, the Kalman filter method requires significant matrix computations, requiring a microcontroller with high computational capability. The accuracy of the Kalman filter method depends on the establishment of an equivalent model, which is difficult to maintain accurately over the battery's entire life due to aging effects.

Combined Voltage Correction Method: For energy storage batteries with constant current charging conditions, a stable charging environment, combining Ah integration with charging curve correction is a commonly used algorithm by manufacturers. This method is highly stable, simple to calculate, and suitable for embedded environments. However, its accuracy depends on the precision of the charging curve. Typically, the factory-tested battery charging curve is used, which changes with battery aging. Using the initial charging curve to correct SOC can lead to unpredictable errors. In scenarios with frequent current changes, such as frequency regulation stations, extracting optimal charging and discharging parameters is challenging.

### SUMMARY OF THE INVENTION

The present disclosure provides a method and a system for estimating a state of charge of a battery cluster, an electronic device, and a storage media, which address and overcome the deficiencies found in current SOC estimation methods.

The aforementioned technical problems of the present disclosure are addressed by the following technical solutions.

A first embodiment of the present disclosure provides a method for estimating a state of charge of a battery cluster, comprising steps S1-S4.
Step S1 comprises acquiring target data related to the state of charge of the battery cluster.
Step S2 comprises estimating, by an ampere-hour integration method, the state of charge of the battery cluster based on the target data, to obtain a first estimated value.
Step S3 comprises inputting the target data into a state-of-charge prediction model to estimate the state of charge of the battery cluster and obtain a second estimated value. The state-of-charge prediction model is obtained by training based on sample data.
Step S4 comprises determining a final estimated value of the state of charge of the battery cluster based on the first estimated value, the second estimated value, and a first distance between the target data and the sample data.

Optionally, step S4 is performed by: performing weighted summation on the first estimated value and the second estimated value to obtain the final estimated value. A first weight K of the first estimated value and a second weight 1−K of the second estimated value are determined based on the first distance.

Optionally, performing the weighted summation on the first estimated value and the second estimated value comprises: determining whether the first distance is greater than a first preset value that is determined based on a maximum distance among the sample data; if yes, configuring the first weight K to be greater than or equal to the second weight 1−K; and if no, configuring the first weight K to be less than the second weight 1−K.

Optionally, the first weight K is obtained by:

$$K = \{ \begin{matrix}1 - \frac{1}{{n}^{D \_ gain}} & D\_gain > 0 , n > 1 \\ 0 & D\_gain \leq 0\end{matrix} , wherein , D\_gain = \frac{D - {D}_{1}}{{D}_{1}} ;$$

where D represents the first distance, D₁ represents the maximum distance among the sample data, and n is a hyper-parameter for representing a convergence speed of the first weight.

Optionally, the target data comprises one or more of a maximum single-battery voltage, a minimum single-battery voltage, an average single-battery voltage, a total voltage, a highest temperature, a lowest temperature, an average temperature, a current, a charging and discharging state, a voltage standard deviation, a temperature standard deviation, and a voltage temperature covariance of the battery cluster.

Optionally, the method for estimating the state of charge of the battery cluster further comprises: when the first distance is greater than a second preset value, adding the target data to the sample data to obtain updated sample data. The second preset value is determined based on the maximum distance among the sample data; and re-training the state-of-charge prediction model with the updated sample data.

Optionally, re-training the state-of-charge prediction model with the updated sample data is performed by: extracting a part of the sample data from the updated sample data by unilateral gradient sampling; and re-training the state-of-charge prediction model with the part of the sample data.

A second embodiment of the present disclosure provides a system for estimating a state of charge of a battery cluster, comprising a data acquisition module, a first estimation module, a second estimation module, and a charge determination module.

The data acquisition module acquires target data related to the state of charge of the battery cluster.

The first estimation module estimates the state of charge of the battery cluster based on the target data by an ampere-hour integration method, to obtain a first estimated value.

The second estimation module inputs the target data into a state-of-charge prediction model to estimate the state of charge of the battery cluster and obtains a second estimated value. The state-of-charge prediction model is obtained by training based on sample data.

The charge determination module determines a final estimated value of the state of charge of the battery cluster based on the first estimated value, the second estimated value, and a first distance between the target data and the sample data.

A third embodiment of the present disclosure provides an electronic device, comprising a memory, a processor, and a computer program stored on the memory and executable on the processor. When the processor executes the computer program, the method as described in any one of the examples provided in the first embodiment of the present disclosure is implemented.

A fourth embodiment of the present disclosure provides a non-transitory computer-readable storage medium, which stores a computer program. The method as described in any one of the examples provided in the first embodiment of the present disclosure is implemented when the computer program is executed by a processor.

Based on the common knowledge in the field, the preferred conditions mentioned above can be freely combined to create various embodiments of the present disclosure.

One significant advancement of the present disclosure lies in combining the ampere-hour integration method and the state-of-charge prediction model to estimate the SOC of the battery cluster. Specifically, the ampere-hour integration method provides a first estimated value of the SOC, while the state-of-charge prediction model provides a second estimated value of the SOC. The first distance between the target data and the sample data reflects the accuracy of the SOC estimated by the prediction model. Based on the first distance, the proportions of the first estimated value and the second estimated value in the final estimated value are determined, effectively improving the accuracy of the SOC estimation for the battery cluster.

Additionally, the present disclosure does not require an in-depth analysis of the internal reaction mechanisms of the battery cluster, the identification of equivalent circuit parameters, or a resting process for the battery cluster, enhancing the accuracy of SOC estimation while reducing cumulative errors.

### BRIEF DESCRIPTION OF DRAWINGS

FIG. 1 is a flowchart of a method for estimating a state of charge of a battery cluster according to Embodiment 1 of the present disclosure.

FIG. 2 is a detailed flowchart of step S41 according to Embodiment 1 of the present disclosure.

FIG. 3 is a flowchart of a method for updating a state-of-charge prediction model according to Embodiment 1 of the present disclosure.

FIG. 4 is a schematic diagram of an estimation effect of the state of charge of the battery cluster according to Embodiment 1 of the present disclosure.

FIG. 5 is a block diagram of a system for estimating the state of charge of the battery cluster according to Embodiment 1 of the present disclosure.

FIG. 6 is a schematic structural diagram of an electronic device according to Embodiment 2 of the present disclosure.

### DETAILED DESCRIPTION OF THE INVENTION

The present disclosure is further described below by means of embodiments, but the scope of the present disclosure is not thereby limited.

### Embodiment 1

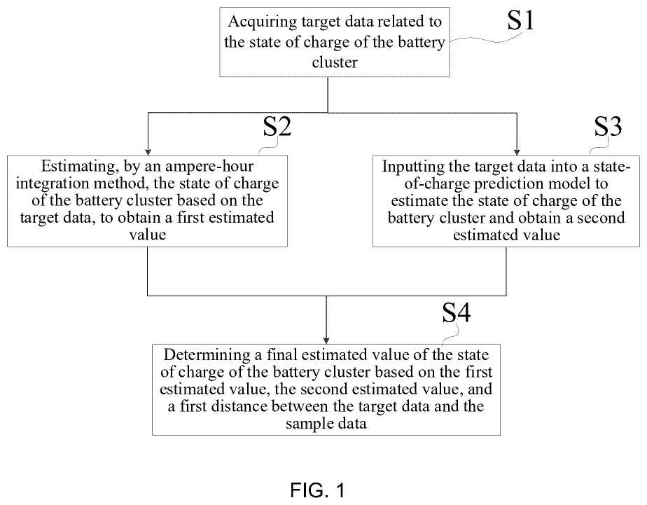

FIG. 1 shows a flowchart of a method for estimating a state of charge of a battery cluster according to Embodiment 1 of the present disclosure. This method can be executed by a system for estimating the state of charge of the battery cluster. This system can be implemented in software and/or hardware and may be a part of or an entire electronic device. The electronic device in Embodiment 1 can be a personal computer (PC), such as a desktop, all-in-one computer, laptop, or tablet; it can also be a mobile phone, wearable device, or personal digital assistant (PDA), among other terminal devices. The following introduces the method for estimating the state of charge of the battery cluster in Embodiment 1 with the electronic device as the execution subject.

As shown in FIG. 1, the method for estimating the state of charge of the battery cluster in Embodiment 1 comprises steps S1-S4.
Step S1 comprises acquiring target data related to the state of charge of the battery cluster.

The target data may also be referred to as data affecting the state of charge of the battery cluster. In order to improve the accuracy of the state of charge estimation, as much target data as possible should be obtained. The battery cluster may comprise a plurality of battery boxes, and each battery box may comprise a plurality of battery cells. The battery cluster comprises sensors for collecting the target data.
Step S2 comprises estimating, by an ampere-hour integration method, the state of charge of the battery cluster based on the target data, to obtain a first estimated value SOCA-

In a specific implementation of step S2, values of the current I, the rated capacity Capacity, and the state of health SOH of the battery cluster in the target data may be substituted into the following formula to calculate the first estimated value SOC_{Ah}:

$${SOC}_{A h} = \frac{I Δ t}{Capacity * SOH} .$$

Step S3 comprises inputting the target data into a state-of-charge prediction model to estimate the state of charge of the battery cluster and obtain a second estimated value SOC_{GBDT}.

The state-of-charge prediction model is obtained by training based on sample data. In a specific implementation, the state-of-charge prediction model can use the gradient boosting decision tree (GBDT), which employs the classification and regression trees (CART). Using GBDT to estimate the state of charge of the battery cluster offers advantages such as fast operation speed and stable results, ensuring the accuracy of the second estimated value SOC_{GBDT}.

In step S3, the target data comprises basic information about the battery cluster, such as a maximum single-battery voltage Vₘₐₓ, a minimum single-battery voltage Vₘᵢₙ, an average single-battery voltage Vₐᵥₑ, a total voltage Vₜₒₜₐₗ, a highest temperature Tₘₐₓ, a lowest temperature Tₘᵢₙ, an average temperature Tₐᵥₑ, a current 1, and a charging and discharging state Charge_state.

Additionally, in step S3, the target data can also comprise statistical information about the battery cluster, such as a voltage standard deviation σᵥ, a temperature standard deviation σ_{T}, and a voltage temperature covariance σ(xₘ,xₖ) of the battery cluster.

The voltage standard deviation oy is obtained by:

$${σ}_{V} = \sqrt{\frac{1}{k} {\sum }_{i = 1}^{k} {( {x}_{i} - {μ}_{V} )}^{2}} ,$$

where μ_{V} represents the average voltage of all single batteries in the battery cluster. The temperature standard deviation or is obtained by:

$${σ}_{T} = \sqrt{\frac{1}{m} {\sum }_{i = 1}^{m} {( {x}_{i} - {μ}_{T} )}^{2}} ,$$

where μ_{T} represents the average value of all temperature measurement points in the battery cluster.
Step S4 comprises determining a final estimated value SOC of the state of charge of the battery cluster based on the first estimated value SOC_{Ah}, the second estimated value SOC_{GBDT}, and a first distance D between the target data and the sample data. Specifically, the proportions of the first estimated value SOC_{Ah} and the second estimated value SOC_{GBDT} in the final estimated value SOC are determined based on the first distance.

In a specific implementation, the first distance may be calculated based on a metric matrix.

The method of the present disclosure combines the ampere-hour integration method and the state-of-charge prediction model to estimate the state of charge of the battery cluster. Specifically, the ampere-hour integration method provides the first estimated value SOC_{Ah} of the state of charge of the battery cluster, while the state-of-charge prediction model provides the second estimated value SOC_{GBDT} of the state of charge of the battery cluster. The first distance reflects the accuracy of the state of charge estimated by the prediction model. Based on the first distance, the proportions of the first estimated value SOC_{Ah} and the second estimated value SOC_{GBDT} in the final estimated value SOC are determined, effectively improving the accuracy of the state of charge estimation for the battery cluster.

In an optional implementation, step S4 specifically comprises step S41.
Step S41 comprises performing weighted summation on the first estimated value and the second estimated value to obtain the final estimated value.

A first weight of the first estimated value and a second weight of the second estimated value are determined based on the first distance.

In a specific implementation, the final estimated value SOC is calculated by:

$$SOC = {SOC}_{GBDT} + K * ( {SOC}_{A h} - {SOC}_{GBDT} ) = K * {SOC}_{A h} + ( 1 - K ) {SOC}_{GBDT} ,$$

where SOC_{GBDT} represents the second estimated value, K represents the first weight of the first estimated value SOC_{Ah}, and 1−K represents the second weight of the second estimated value.

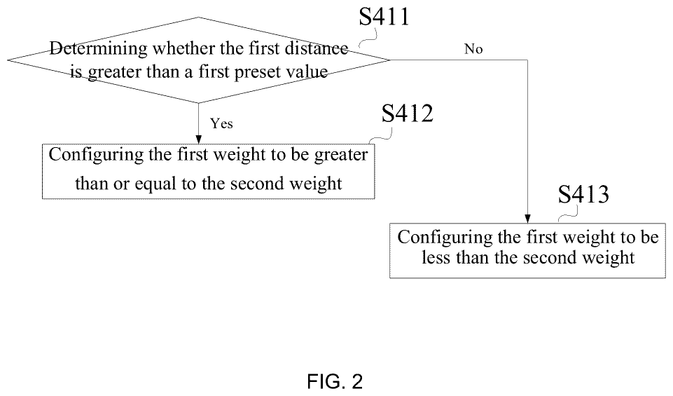

In an optional implementation, as show in FIG. 2, step S41 comprises step S411-S413.
Step S411 comprises determining whether the first distance is greater than a first preset value; if yes, performing S412; and if no, directly performing S413.

The first preset value can be determined based on a maximum distance D₁ among the sample data.
S412 comprises configuring the first weight to be greater than or equal to the second weight.
S413 comprises configuring the first weight to be less than the second weight.

In a specific implementation, if the first distance is greater than the first preset value, it indicates that the target data is not comprised in the sample data, during which time, the first estimated value using the ampere-hour integration method has a higher proportion in the final estimated value than the second estimated value; if the first distance is less than or equal to the first preset value, it indicates that the target data is comprised in the sample data, during which time, the second estimated value obtained by the state-of-charge prediction model has a higher proportion in the final estimated value than the first estimated value.

In an optional implementation, the first weight K is calculated by:

$$K = \{ \begin{matrix}1 - \frac{1}{{n}^{D \_ gain}} & D\_gain > 0 , n > 1 \\ 0 & D\_gain \leq 0\end{matrix} , wherein , D\_gain = \frac{D - {D}_{1}}{{D}_{1}} ;$$

where D represents the first distance, D₁ represents the maximum distance among the sample data, n is a hyper parameter representing a convergence speed of the first weight and is adjustable based on the actual situation, and 1−K represents the second weight.

In a specific implementation, if D_gain≤0, it indicates that the target data is comprised in the sample data, at which time, set K=0, meaning the second estimated value (i.e., the state of charge estimated by the prediction model) has a higher proportion in the final estimated value than the first estimated value; and if D_gain>0, it indicates that the target data is not comprised in the sample data, and the larger the value of D_gain, the greater the distance, and K will approach 1, meaning the first estimated value (i.e., the state of charge estimated by using the ampere-hour integration method) has a higher proportion in the final estimated value than the second estimated value. By using the final estimated value, which combines the ampere-hour integration method with the prediction model, the accuracy of the state of charge estimation is significantly improved, optimizing charging and discharging strategies for battery clusters.

The following provides a detailed introduction to the training process of the state-of-charge prediction model mentioned above.

An energy storage station is equipped with multiple battery clusters that generate a large amount of historical data daily. The sample data, along with the corresponding state-of-charge, can be selected from the historical data for training the state-of-charge prediction model. Suppose there are N pieces of sample data {\vec{x}₁, \vec{x}₂ . . . \vec{x}ₙ}, with corresponding state of charge {y₁, y₂ . . . y_{N}}, the loss function is L (y, f (x)), the number of iterations is M, and the strong learner for building the state-of-charge prediction model is \hat{f}(x). The training process of the state-of-charge prediction model comprises steps (1)-(3).
Step (1): Initialize the weak learner

$${f}_{0} ( x ) = {arg min}_{c} {\sum }_{i = 1}^{N} L ( {y}_{i} , c ) ,$$

where c is usually the average value of all the sample data corresponding to the real state of charge.
Step (2): For the number of iterations m, wherein m=1, 2, . . . , M:
a. For each piece of sample data i=1, 2, . . . , N, calculate the negative gradient (i.e., residual):

$${g}_{m i} = - {[ \frac{\partial L ( {y}_{i} , f ( {x}_{i} ) )}{\partial f ( {x}_{i} )} ]}_{f ( x ) = {f}_{m - 1} ( x )} ;$$

b. Use the residual as the new real state of charge for the sample data and use the data (xᵢ, gₘᵢ) (i=1, 2, . . . . N) as training data for the next tree to obtain a regression tree Rₘⱼ, j=1, 2 . . . , J, where J is the number of leaf nodes.
c. Calculate the optimal fit value for each leaf region j=1, 2 . . . , J:

$${c}_{mj} = {\sum }_{x i ∈ {R}_{mj}} L ( {y}_{i} , {f}_{m - 1} ( {x}_{i} ) + c ) ;$$

d. Update the strong learner

$${f}_{m} ( x ) = {f}_{m - 1} ( x ) + {\sum }_{j = 1}^{J} {c}_{mj} I ( x ∈ {R}_{mj} ) ;$$

(3) Obtain the final learner

$$\hat{f} ( x ) = {\sum }_{m = 1}^{M} {\sum }_{j = 1}^{J} {c}_{mj} I ( x ∈ {R}_{mj} ) .$$

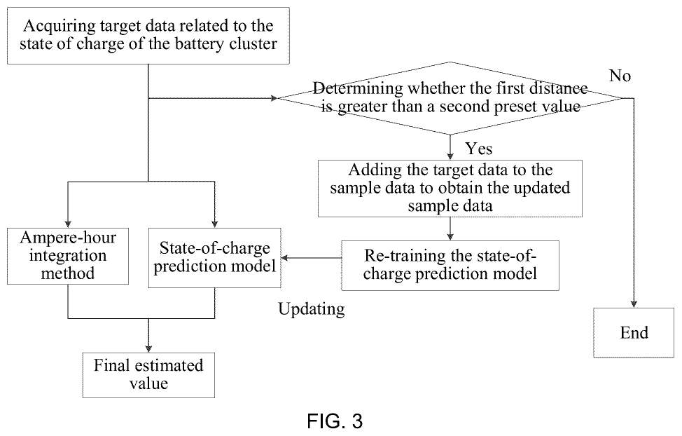

To further improve the accuracy of the state of charge of the battery cluster estimated by the state-of-charge prediction model, the sample data can be updated based on the obtained target data, and the state-of-charge prediction model can be retrained with the updated sample data. In an optional implementation, as shown in FIG. 3, when the first distance is greater than a second preset value, the target data is added to the sample data to obtain the updated sample data, and the state-of-charge prediction model is retrained using the updated sample data. The second preset value is determined based on the maximum distance among the sample data. In a specific implementation, the second preset value can be the same as or greater than the first preset value.

As an example, the updated sample data comprises the original sample data and qualified target data. Qualified target data are those whose distance from the sample data is greater than the second preset value.

In a specific implementation, to avoid frequent retraining of the state-of-charge prediction model, the sample data can be reconstructed and the prediction model can be retrained when the qualified target data reaches a certain quantity.

In an optional implementation, the state-of-charge prediction model is retrained by: extracting a part of the sample data from the updated sample data using unilateral gradient sampling, and re-training the state-of-charge prediction model with the part of the sample data. Specifically, the sample data used to re-train the state-of-charge prediction model is first extracted through the unilateral gradient sampling, then a new tree is fitted by extracting the residuals of the sample data, and finally, the state-of-charge prediction model is updated to obtain the latest strong learner.

In a specific implementation, the negative gradient of the updated sample data is calculated by:

$${g}_{i} = - [ \frac{\partial L ( {y}_{i} , f ( {x}_{i} ) )}{\partial f ( {x}_{i} )} ] .$$

The sample data is sorted in descending order based on the absolute value of the negative gradient, the first A pieces of sample data are extracted, and B pieces of sample data are randomly selected from the remaining sample data to obtain (A+B) pieces of sample data. To ensure that these (A+B) pieces of sample data are consistent with the distribution space of the original sample data, a coefficient

$$\frac{( 1 - a )}{b}$$

is used for multiplication when calculating the residuals of B pieces of sample data, where a represents the percentage of A pieces of sample data in the total sample data and b represents the percentage of B pieces of sample data in the total sample data.

It should be noted that after updating the state-of-charge prediction model, the maximum distance D₁ among the sample data should also be updated.

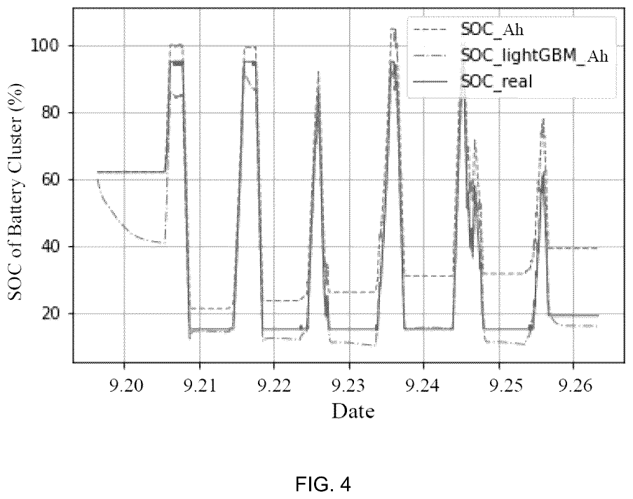

FIG. 4 shows a schematic diagram of an estimation effect of the state of charge of the battery cluster according to the present disclosure. It can be seen from FIG. 4 that there is a cumulative error in the state of charge (marked as SOC_Ah) of the battery cluster estimated by using the ampere-hour integration method, which is much different from the real state of charge (marked as SOC_real) of the battery cluster, and the state of charge (marked as SOC_lightGBM_Ah) of the battery cluster estimated by using the method provided in the present disclosure shows minimal deviation from the real state of charge of the battery cluster, resulting in higher accuracy.

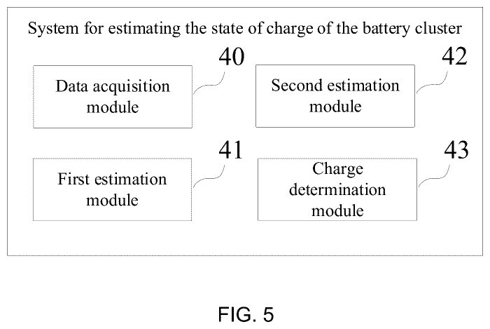

The present disclosure further provides a system for estimating the state of charge of the battery cluster, as shown in FIG. 5, comprising a data acquisition module 40, a first estimation module 41, a second estimation module 42, and a charge determination module 43.

The data acquisition module 40 acquires the target data related to the state of charge of the battery cluster.

The first estimation module 41 estimates the state of charge of the battery cluster based on the target data by using the ampere-hour integration method, to obtain the first estimated value.

The second estimation module 42 inputs the target data into the state-of-charge prediction model to estimate the state of charge of the battery cluster and obtains the second estimated value. The state-of-charge prediction model is obtained by training based on the sample data.

The charge determination module 43 determines the final estimated value of the state of charge of the battery cluster based on the first estimated value, the second estimated value, and the first distance between the target data and the sample data.

In an optional implementation, the charge determination module 43 performs weighted summation on the first estimated value and the second estimated value to obtain the final estimated value. The first weight of the first estimated value and the second weight of the second estimated value are determined based on the first distance.

In an optional implementation, the charge determination module 43 is specifically configured to determine whether the first distance is greater than the first preset value that is determined based on the maximum distance among the sample data; if yes, the first weight is configured to be greater than or equal to the second weight; and if no, the first weight is configured to be less than the second weight.

In an optional implementation, the target data comprises one or more of a maximum single-battery voltage, a minimum single-battery voltage, an average single-battery voltage, a total voltage, a highest temperature, a lowest temperature, an average temperature, a current, a charging and discharging state, a voltage standard deviation, a temperature standard deviation, and a voltage temperature covariance of the battery cluster.

In an optional implementation, the system further comprises a model training module, configured to add the target data into the sample data when the first distance is greater than the second preset value, to obtain the updated sample data. The second preset value is determined based on the maximum distance among the sample data. The state-of-charge prediction model is retrained using the updated sample data.

In an optional implementation, the model training module extracts a part of the sample data from the updated sample data using unilateral gradient sampling, and re-trains the state-of-charge prediction model with the part of the sample data.

It should be noted that, the presently disclosed system can be a standalone chip, chip module, or electronic device; it can also be a chip or chip module integrated into an electronic device.

The various modules/units included in the presently disclosed system can be software modules/units, hardware modules/units, or a combination of both.

### Embodiment 2

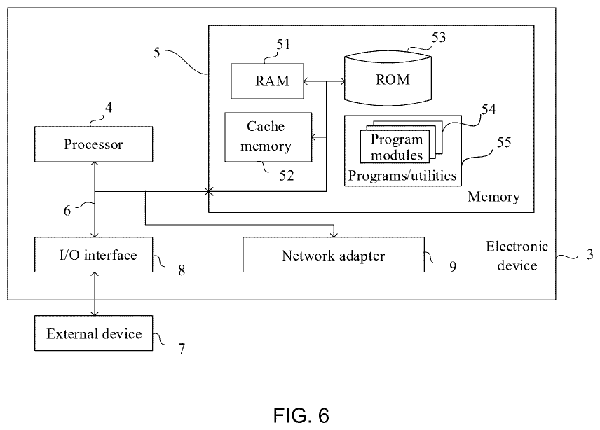

FIG. 6 shows a schematic structural diagram of an electronic device 3 according to the present disclosure. The electronic device 3 comprises at least one processor and at least one memory that communicates with the processor. The memory stores a computer program that can be run by the processor, enabling the processor to execute the method as described in Embodiment 1. The electronic device 3 can be a personal computer (PC), such as a desktop, all-in-one computer, laptop, or tablet; it can also be a mobile phone, wearable device, or personal digital assistant (PDA), among other terminal devices. Accordingly, the electronic device 3 shown in FIG. 6 is exemplary.

Exemplarily, the components of the electronic device 3 comprise at least one processor 4, at least one memory 5, and a bus 6 that connects various system components (including memory 5 and processor 4).

The bus 6 comprises a data bus, an address bus, and a control bus.

The memory 5 may comprise volatile memory such as Random Access Memory (RAM) 51 and/or cache memory 52, and may also comprise Read-Only Memory (ROM) 53.

Additionally, the memory 5 may further comprise programs/utilities 55 that include at least one program module 54. The program module 54 comprises an operating system, one or more applications, other program modules, and program data. Each of these examples, or a combination thereof, may include implementations in a network environment.

The processor 4 executes various functional applications and data processing tasks by running the computer program stored in the memory 5, such as the method for estimating the state of charge of the battery cluster described above.

The electronic device 3 may also communicate with one or more external devices 7 (e.g., keyboard, pointing device) through an input/output (I/O) interface 8. Additionally, the electronic device 3 may communicate with one or more networks (e.g., local area network (LAN), wide area network (WAN), and/or public networks such as the Internet) through a network adapter 9. As shown in FIG. 6, the network adapter 9 communicates with other modules of the electronic device 3 through the bus 6. Although not shown in FIG. 6, it should be understood that other hardware and/or software modules can be used in conjunction with the electronic device 3, including but not limited to microcode, device drivers, redundant processors, external disk drive arrays, Redundant Array of Independent Disk (RAID) systems, tape drives, and data backup storage systems.

It should be noted that although several units/modules or sub-units/modules of the electronic device are mentioned in the detailed description above, this division is merely exemplary and not mandatory. In practice, according to the examples described herein, the features and functions of two or more units/modules described above can be embodied in a single unit/module. Conversely, the features and functions of a single unit/module described above can be further divided and embodied in multiple units/modules.

### Embodiment 3

The present disclosure further provides a non-transitory computer-readable storage medium which stores a computer program. The method as described in Embodiment 1 of the present disclosure is implemented when the computer program is executed by a processor.

The non-transitory computer-readable storage medium may comprise portable disks, hard disks, RAM, ROM, erasable programmable read-only memory (EPROM), optical storage devices, magnetic storage devices, or any suitable combination thereof.

In an alternative implementation, the presently disclosed non-transitory computer-readable storage medium can also be realized as a program product comprising program code. When the program product is run on an electronic device, the program code enables the electronic device to perform the method as described in Embodiment 1 of the present disclosure.

The program code can be written in any combination of one or more programming languages and can be executed entirely on the electronic device, partially on the electronic device, as a standalone software package, partially on the electronic device and partially on a remote device, or entirely on a remote device.

Although specific embodiments of the present disclosure are described above, those skilled in the art will understand that these are merely illustrative and not restrictive. The scope of the present disclosure is defined by the claims. Those skilled in the art can make various changes or modifications to these embodiments without departing from the principles and spirit of the present disclosure, and such changes and modifications falls within the scope of the present disclosure.

1. A method for estimating a state of charge of a battery cluster, comprising:
S1: acquiring target data related to the state of charge of the battery cluster;
S2: estimating, by an ampere-hour integration method, the state of charge of the battery cluster based on the target data, to obtain a first estimated value;
S3: inputting the target data into a state-of-charge prediction model to estimate the state of charge of the battery cluster and obtain a second estimated value, wherein the state-of-charge prediction model is obtained by training based on sample data; and
S4: determining a final estimated value of the state of charge of the battery cluster based on the first estimated value, the second estimated value, and a first distance between the target data and the sample data.

2. The method according to claim 1, wherein S4 is performed by:
performing weighted summation on the first estimated value and the second estimated value to obtain the final estimated value;
wherein a first weight of the first estimated value and a second weight of the second estimated value are determined based on the first distance.

3. The method according to claim 2, wherein performing the weighted summation on the first estimated value and the second estimated value comprises:
determining whether the first distance is greater than a first preset value that is determined based on a maximum distance among the sample data;
if yes, configuring the first weight to be greater than or equal to the second weight; and
if no, configuring the first weight to be less than the second weight.

4. The method according to claim 3, wherein the first weight is obtained by:
$$K = \{ \begin{matrix}1 - \frac{1}{{n}^{D \_ gain}} & D\_gain > 0 , n > 1 \\ 0 & D\_gain \leq 0\end{matrix} , wherein , D\_gain = \frac{D - {D}_{1}}{{D}_{1}} ;$$
where D represents the first distance, D₁ represents the maximum distance among the sample data, and n is a hyper-parameter for representing a convergence speed of the first weight.

5. The method according to claim 1, wherein the target data comprises one or more of a maximum single-battery voltage, a minimum single-battery voltage, an average single-battery voltage, a total voltage, a highest temperature, a lowest temperature, an average temperature, a current, a charging and discharging state, a voltage standard deviation, a temperature standard deviation, and a voltage temperature covariance of the battery cluster.

6. The method according to claim 1, further comprising:
when the first distance is greater than a second preset value, adding the target data to the sample data to obtain updated sample data, wherein the second preset value is determined based on the maximum distance among the sample data; and
re-training the state-of-charge prediction model with the updated sample data.

7. The method according to claim 6, wherein re-training the state-of-charge prediction model with the updated sample data is performed by:
extracting a part of the sample data from the updated sample data by unilateral gradient sampling; and
re-training the state-of-charge prediction model with the part of the sample data.

8. A system for estimating a state of charge of a battery cluster, comprising:
a data acquisition module, which acquires target data related to the state of charge of the battery cluster;
a first estimation module, which estimates the state of charge of the battery cluster based on the target data by an ampere-hour integration method, to obtain a first estimated value;
a second estimation module, which inputs the target data into a state-of-charge prediction model to estimate the state of charge of the battery cluster and obtains a second estimated value, wherein the state-of-charge prediction model is obtained by training based on sample data; and
a charge determination module, which determines a final estimated value of the state of charge of the battery cluster based on the first estimated value, the second estimated value, and a first distance between the target data and the sample data.

9. An electronic device, comprising a memory, a processor, and a computer program stored on the memory and executable on the processor, wherein when the processor executes the computer program, the method according to claim 1 is implemented.

10. A non-transitory computer-readable storage medium, which stores a computer program, wherein the method according to claim 1 is implemented when the computer program is executed by a processor.
